(19) United States
(12) Patent Application Publication
(10) Pub. No.: US 2005/0104222 A1
(43) Pub. Date: May 19, 2005

(54) Flip chip device having supportable bar and mounting structure thereof

(76) Inventors: Se-Young Jeong, Seoul (KR); Gu-Sung Kim, Seongnam-si (KR); Nam-Seog Kim, Cheonan-si (KR); Gi-Hwan Park, Cheonan-si (KR); Se-Yong Oh, Yongin-si (KR); Soon-Bum Kim, Suwon-si (KR); In-Young Lee, Yongin-si (KR)

Correspondence Address: HARNESS, DICKEY & PIERCE, P.L.C., P.O. BOX 8910, RESTON, VA, 20195, US

(21) Appl. No.: 10/944,613

(22) Filed: Sep. 20, 2004

(30) Foreign Application Priority Data
Oct. 22, 2003 (KR) 2003-73862

(51) Int. Cl. H01L 23/48

(52) U.S. Cl. 257/778; 257/779; 257/780; 257/784

(57) ABSTRACT

A flip chip device may have a semiconductor chip with an active surface on which chip pads and a protective layer may be provided. Solder bumps may be provided on the active surface and electrically connected to the chip pads. And a solder bar may be provided on a portion of the protective layer. The solder bar may disperse thermal stress produced in the solder bumps. A metal core may be embedded within the solder bar. The flip chip device may be mounted on and flip-chip bonded to a substrate. The substrate may have land pads to which the solder bumps and the solder bar may be mechanically joined. The solder bar increases a joint area between the flip chip device and the substrate and reinforces solder connections therebetween.

### CROSS REFERENCE TO RELATED APPLICATIONS

This U.S. non-provisional application claims priority under 35 U.S.C. §119 to Korean Patent Application No. 2003-73862 filed Oct. 22, 2003, the contents of which are incorporated herein in its entirety by reference.

### BACKGROUND OF THE INVENTION

1. Field of the Invention

The present invention relates generally to electronic packaging technology and, more particularly, to flip chip technology using solder bump interconnections.

2. Description of the Related Art

As in other sectors of the semiconductor industry, the electronic packaging industry is driven by the demand for packages that are smaller, faster and cheaper. A chip size package (CSP) has been developed to satisfy the industry's growing demand for the smallest, i.e., chip-sized, form factor as required in smaller and advanced electronic end-applications. Additionally, a wafer level package (WLP) has been recently introduced to realize cost-effective fabrication of packages on the wafer prior to singulation. Flip chip (FC) technology may be the main stream of the electronic packaging industry.

Flip chip technology is the mounting of a bare chip onto a substrate with an active side of the bare chip facing the substrate. The electrical interconnection between the chip and the substrate may be established by solder bumps, for example. As compared to other conventional packaging techniques, flip chip technology may offer better electrical performance due to shorter electrical paths between the chip and the substrate.

The flip chip using the solder bumps may require the dispensing of an underfill material after the solder bumped chip has been attached to the substrate by a solder reflow process. The underfill material may be dispensed alongside the chip and drawn between the chip and the substrate via capillary action, thereby surrounding the solder bumps. The underfill material is used to protect the interconnect area from moisture. It also reinforces the mechanical connection between the chip and the substrate. The underfill material compensates for any difference in the coefficient of thermal expansion (CTE) between the silicon chip and the substrate.

Although the conventional flip chip technology is generally thought to provide acceptable packaging characteristics, it is not without shortcomings. Namely, due to the underfill material, it may be more difficult to produce miniaturized devices. For example, as the size of the solder bump is reduced, a gap between the chip and the substrate may be decreased. However, the reduction in the size of the gap may be limited by the dimension of the fillers contained in the underfill material. Accordingly, the dimension of fillers contained in the underfill material may become a manufacturing constraint. New underfill material having smaller fillers might solve the above-discussed issue. However, the development of such new underfill material also might invite an increase in production cost and further require adequate equipments and processes.

### SUMMARY OF THE INVENTION

According to exemplary, non-limiting embodiments of the present invention, a flip chip device is not provided with underfill material (as in conventional packages), but nevertheless compares to conventional packages in terms of reliability.

According to one exemplary embodiment of the present invention, the semiconductor device includes a semiconductor chip having an active surface, a plurality of chip pads formed on the active surface, and a protective layer formed on the active surface, such that the chip pads exposed through the active surface. A plurality of solder bumps may be formed on the active surface and electrically connected to the respective chip pads. A solder bar may be provided on a portion of the protective layer. The solder bar may disperse thermal stress produced in the solder bumps.

According to another exemplary embodiment of the present invention, the device may further include an under bump metal layer interposed between the solder bar and the protective layer. Also, the device may further include at least one metal core formed on the under bump metal layer and embedded within the solder bar. The metal core may be fabricated from nickel (Ni), copper (Cu), platinum (Pt), palladium (Pd), gold (Au) and alloys thereof.

According to still another exemplary embodiment of the present invention, a structure is provided in which the semiconductor device is mounted on a substrate. The semiconductor device includes a semiconductor chip having an active surface, a plurality of chip pads formed on the active surface, and a protective layer formed on the active surface, such that the chip pads are exposed through the protective layer. A plurality of solder bumps are provided on the active surface and electrically connected to the respective chip pads. A solder bar is provided on a portion of the protective layer. The substrate includes first land pads to which the solder bumps are joined and a second land pad to which the solder bar is joined.

According to yet another exemplary embodiment of the present invention, the device may further include an under bump metal layer interposed between the solder bar and the protective layer. And, the device may further include at least one metal core formed on the under bump metal layer and embedded within the solder bar. Also, the substrate may further include at least one metal core formed on the second land pad and embedded within the solder bar.

### BRIEF DESCRIPTION OF THE DRAWINGS

Various features of the present invention will become readily apparent from the description of the exemplary embodiments that follows, with reference to the attached drawings in which:

FIG. 1 is a perspective view of a flip chip device having a solder bar in accordance with an exemplary, non-limiting embodiment of the present invention.

FIG. 2 is a cross-sectional view taken along the line II-II of FIG. 1.

FIG. 3 is an exploded perspective view of a mounting structure of the flip chip device shown in FIG. 1.

FIG. 4 is cross-sectional view taken along the line IV-IV of FIG. 3.

FIG. 5 is an exploded perspective view of another mounting structure of the flip chip device shown in FIG. 1.

FIG. 6 is cross-sectional view taken along the line VI-VI of FIG. 5.

FIG. 7 is a perspective view of a flip chip device having a solder bar in accordance with another exemplary, non-limiting embodiment of the present invention.

FIG. 8 is a cross-sectional view taken along the line VIII-VIII of FIG. 7.

FIG. 9 is a partially cut away perspective view of a flip chip device having a solder bar in accordance with another exemplary, non-limiting embodiment of the present invention.

FIG. 10 is a cross-sectional view taken along the line X-X of FIG. 9.

FIG. 11 is a cross-sectional view of a mounting structure of the flip chip device shown in FIG. 9.

FIG. 12 is a cross-sectional view of another mounting structure of the flip chip device shown in FIG. 9.

FIG. 13 is a partially cut away perspective view of a flip chip device having a solder bar in accordance with another, non-limiting embodiment of the present invention.

### DETAILED DESCRIPTION OF EXEMPLARY EMBODIMENTS OF THE INVENTION

Exemplary embodiments of the present invention will now be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art.

It is to be appreciated that the figures are not drawn to scale. Rather, for simplicity and clarity of illustration, the dimensions of some of the elements are exaggerated relative to other elements. Like numerals are used for like and corresponding parts of the various drawings.

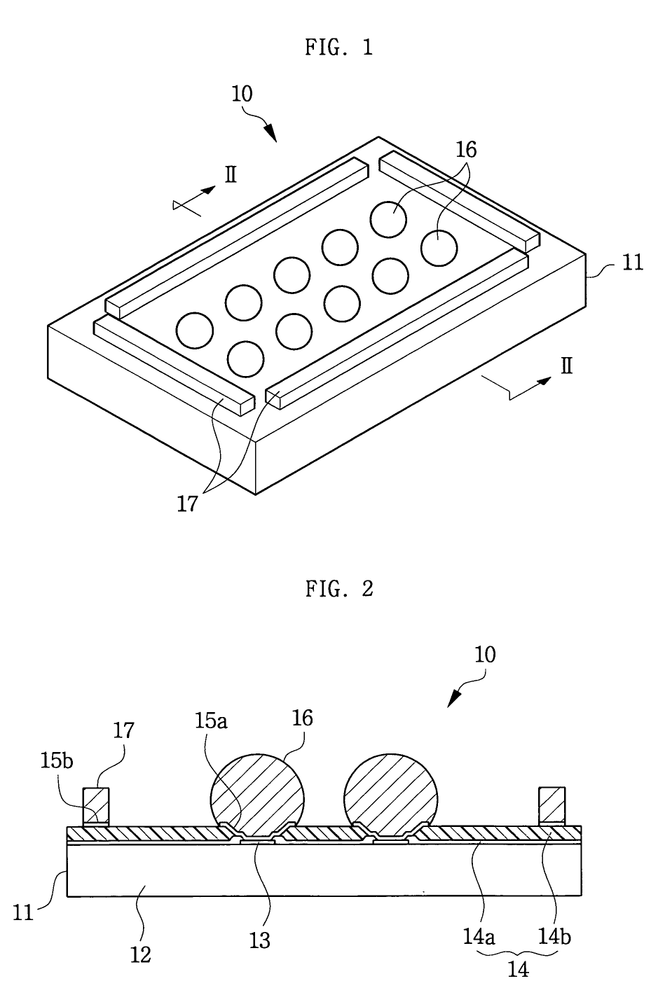

FIG. 1 shows, in a perspective view, a flip chip device 10 having a solder bar 17 in accordance with an exemplary embodiment of the present invention. Further, FIG. 2 is a cross-sectional view taken along the line II-II of FIG. 1.

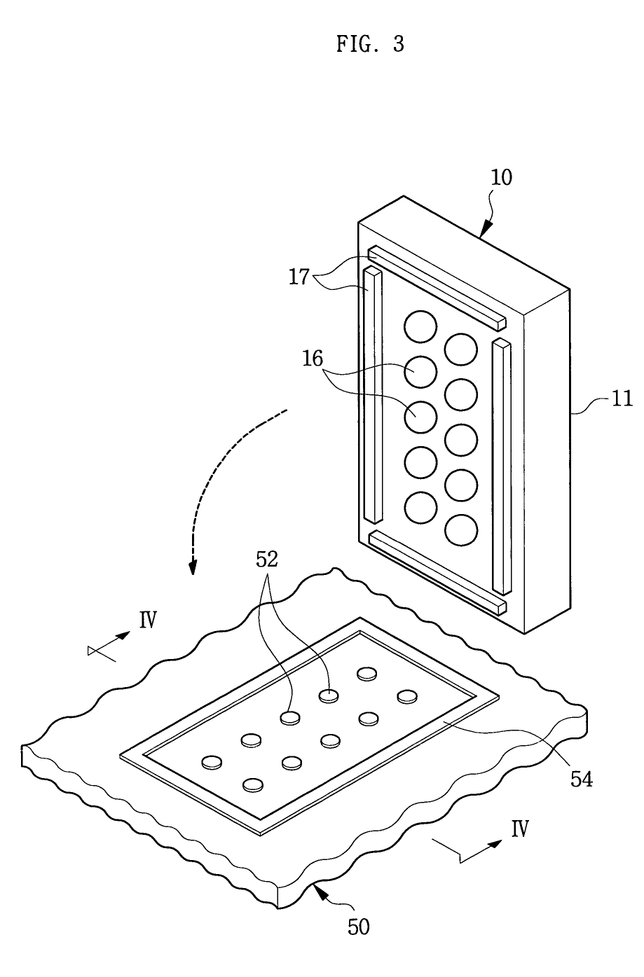

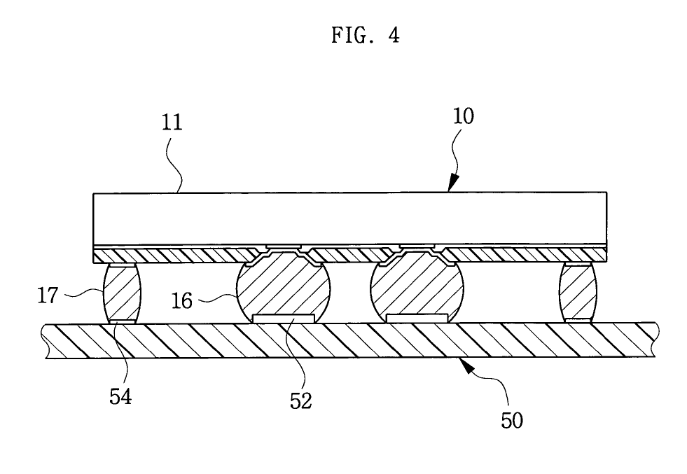

Referring to FIGS. 1 and 2, the device 10 is a flip chip device that may be mounted to a substrate in a flip-chip fashion, (i.e., so that the active surface of the device 10 faces the substrate 50, as shown in FIGS. 3 and 4). The flip chip device 10 may be fabricated, for example, at a wafer level like a wafer level package. The flip chip device 10 may have a plurality of solder bumps 16 formed on respective chip pads 13 of a semiconductor chip 11. In this exemplary embodiment, the solder bar 17 may be provided around the solder bumps 16 so as to disperse thermal stress produced in the solder bumps 16.

The chip pads 13 may be disposed on the active surface of the chip 11. The chip pads 13 may be electrically connected to integrated circuits (not shown) that are provided in a substrate 12 of the chip 11. The substrate 12 may be fabricated from silicon or some other suitable material, as is well known in this art. The chip pads 13 may be fabricated from mainly aluminum (Al). However, many other suitable materials are well known in this art and therefore a detailed description of the same is not provided. The chip pads 13 in this exemplary embodiment may be arranged in a central region of the active surface. Accordingly, this type of chip 11 may be referred to as a center pad type chip.

The active surface of the chip 11, except for the chip pads 13, may be covered with at least one protective layer 14; i.e., the chip pads 13 are exposed through the protective layer 14. The protective layer 14 may be composed of a passivation layer 14a and an insulating layer 14b. The passivation layer 14a may be fabricated from silicon oxide or silicon nitride having a thickness of about 0.5 μm, while the insulating layer 14b may be fabricated from polyimide having a thickness of about 4.5 μm. It will be appreciated that the disclosed materials and thicknesses of the passivation layer 14a and the insulating layer 14b are exemplary only. Other suitable materials and thicknesses are well known in this art, and therefore a detailed description of the same is omitted. As shown in FIG. 2, the protective layer 14 may be interposed between the solder bar 17 and the chip 11, thereby electrically insulating the solder bar 17 from the chip 11.

An under bump metal (UBM) layer 15a and 15b may be formed on the active surface of the chip 11 beneath the solder bumps 16 and the solder bar 17. For example, a part 15a of the UBM layer may be formed on the chip pads 13, and another part 15b of the UBM layer may be formed on the protective layer 14 in peripheral regions of the active surface. The UBM layer 15a and 15b may act (for example) as an adhesive layer, a diffusion barrier, a plating base, and a solder wetting layer. The UBM layer 15a and 15b may be formed by sputtering, chemical vapor deposition (CVD), or any other conventional layer forming technique that is well known in this art. The UBM layer may be composed of various metals such as titanium and nickel (Ti/Ni), titanium and copper (Ti/Cu), titanium, titanium-copper and copper (Ti/Ti—Cu/Cu), chromium, chromium-copper and copper (Cr/Cr—Cu/Cu), titanium tungsten and copper (TiW/Cu), aluminum, nickel and copper (Al/Ni/Cu), or aluminum, nickel vanadium and copper (Al/Ni/Cu). It will be appreciated that other suitable materials are well known in this art, and therefore a detailed discussion of the same is omitted.

The solder bumps 16 and the solder bar 17 may be formed on the UBM layer 15a and 15b. Those skilled in art will appreciate that the solder bar 17 may be formed simultaneously with the solder bumps 16, without separate and additional process steps. The solder bumps 16 and the solder bar 17 may be fabricated using well known methods, including for example (but not limited to), ball placement, electroplating, stencil printing, and metal jetting. The electroplating method may be implemented when smaller solder bumps are required. The solder bumps 16 and the solder bar 17 may be fabricated from mainly tin (Sn) and additionally include one or more of lead (Pb), nickel (Ni), silver (Ag), copper (Cu), bismuth (Bi), and their alloy. It will be appreciated, however, that the list of materials is presented by way of illustration only, and not as a limitation of the invention. Many suitable, alternative materials are well known in this art, and therefore a detailed description of the same is omitted.

The solder bar 17 in this exemplary, non-limiting embodiment has a rectangular frame-like shape that surrounds the solder bumps 16, but this shape is exemplary only and not to be considered as a limitation of exemplary embodiments of the invention. For example, the solder bar 17 may be provided in a discontinuous fashion (as shown in FIG. 1), or alternatively in a continuous fashion. Further, the solder bar 17 may have straight sides (as shown in FIG. 1) or sides that are curved. The solder bar 17 may be of any height, but preferably not of a height greater than that of the solder bumps 16.

As discussed above, the device 10 according to an exemplary embodiment of the present invention is a flip chip device and may be fabricated at a wafer level. Further, the flip chip device 10 may be applied to chip size packages. The solder bumps 16 in this exemplary embodiment may be formed just above the chip pads 13 without rerouting. It will be appreciated, however, that the chip pads 13 may be rerouted to form an area array configuration.

The flip chip device 10 may be mounted on and flip-chip bonded to a substrate as shown in FIGS. 3 and 4. FIG. 3 is an exploded perspective view of an exemplary mounting structure of the flip chip device 10, and FIG. 4 is a cross-sectional view taken along the line IV-IV of FIG. 3. Referring to FIGS. 3 and 4, the substrate 50 has a mounting surface (i.e., the surface facing upward in FIGS. 3 and 4) on which may be provided two kinds of land pads 52 and 54. When the device 10 is mounted on the substrate 50, the solder bumps 16 and the solder bar 17 of the device 10 may be respectively placed on the land pads 52 and 54 and then mechanically joined thereto via a solder reflow process. The solder reflow process is well known in this art and therefore a detailed description of the same is omitted. The first land pad 52, which may be provided under the solder bump 16, may have a circular shape, and the second land pad 54, which may provided under the solder bar 17, may have a rectangular frame-like shape (i.e., a shape that may generally correspond to the shape of the solder bar 17). It will be appreciated, however, that the land pads 52, 54 may have a variety of shapes. For example, the land pads 52 may have a square, triangle, or other geometric shape. Also, the land pad 54 may be provided in a continuous fashion (as shown), or alternatively may be provided in a discontinuous fashion.

The solder bar 17 may increase a joint area between the device 10 and the substrate 50, and therefore mechanically reinforces the electrical connections (which are provided via the solder bumps 16) between the device 10 and the substrate 50. Also, the solder bar 17 absorbs thermal stress that may be concentrated on the solder bumps 16 due to a difference in the coefficient of thermal expansion (CTE) between the flip chip device 10 and the substrate 50. Such thermal stresses may occur, for example, during the solder reflow process. For these reasons, though a conventional underfill material is not used, the present embodiment, by virtue of the solder bar 17 achieves a reliability that is comparable to conventional flip chip packages.

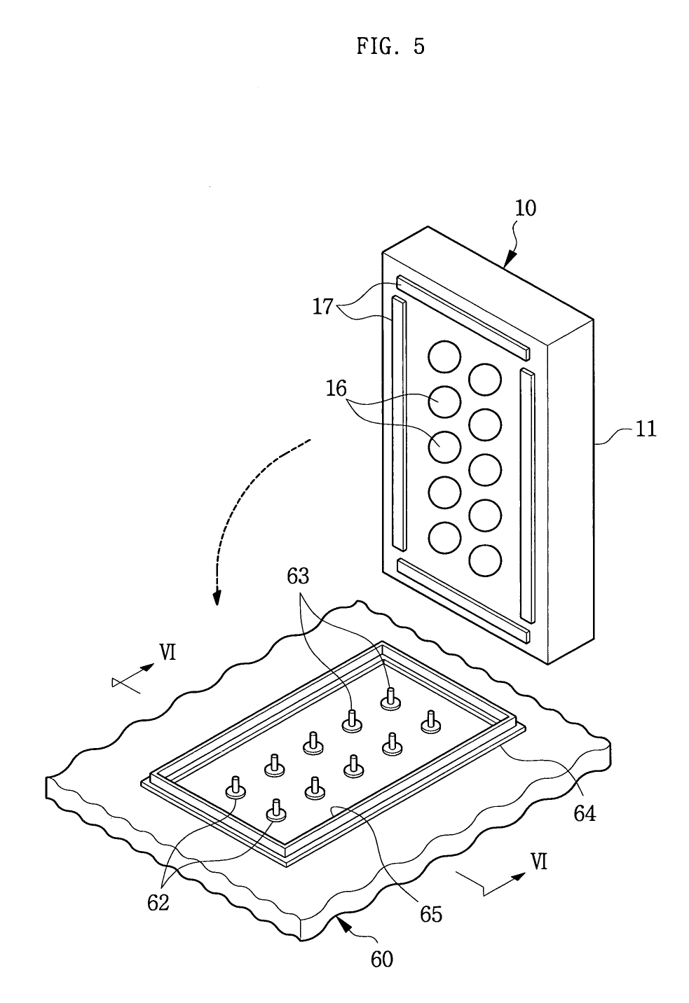

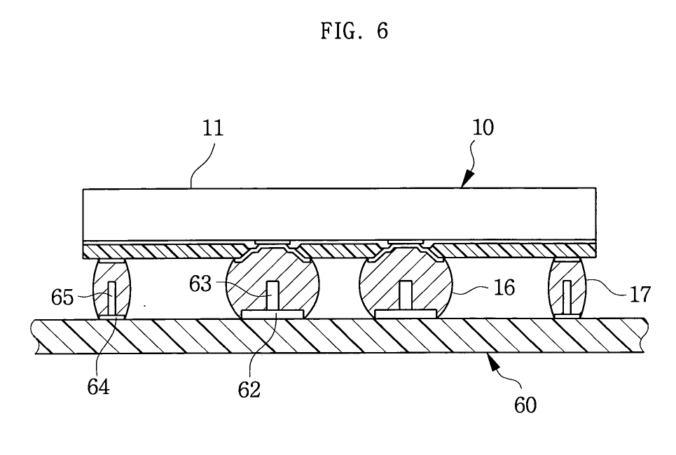

The flip chip device 10 shown in FIGS. 1 and 2 may be flip-chip bonded to another substrate, as shown in FIGS. 5 and 6. FIG. 5 is an exploded perspective view of another mounting structure of the flip chip device 10, and FIG. 6 is cross-sectional view taken along the line VI-VI of FIG. 5. Here, the substrate 60 may have first land pads 62 for the solder bumps 16 and a second land pad 64 for the solder bar 17. First metal cores 63 may extend from the respective first land pads 62, and a second metal core 65 may extend from the second land pad 64. The first and the second metal cores 63 and 65 may be fabricated from one or more of nickel (Ni), copper (Cu), platinum (Pt), palladium (Pd), gold (Au) and their alloy. The first and the second metal cores 63 and 65 may be made of the same material as the solder bumps 16 and the solder bar 17. This list of materials is exemplary only, and not intended to limit the invention. It will be appreciated that other suitable materials are well known in this art, and therefore a detailed description of the same is omitted.

When the solder reflow process is carried out, the solder bumps 16 and the solder bar 17 may be joined respectively to the land pads 62 and 64. In so doing, the first and the second metal cores 63 and 65 may be respectively embedded within the solder bumps 16 and the solder bar 17. Therefore, the metal cores 63 and 65 may act as framework of the solder joints, reinforcing the mechanical connection of the solder bumps 16 and the solder bar 17 against thermal stress.

The metal cores 63 in the solder bumps 16 may be formed, for example, by the process described in applicant's Korean Patent Application No. 2003-65946 corresponding to U.S. application Ser. No. 10/825,199, the disclosures of both being hereby incorporated by reference. The second metal core 65 in this embodiment may be formed simultaneously with the first metal cores 63 in the same manner.

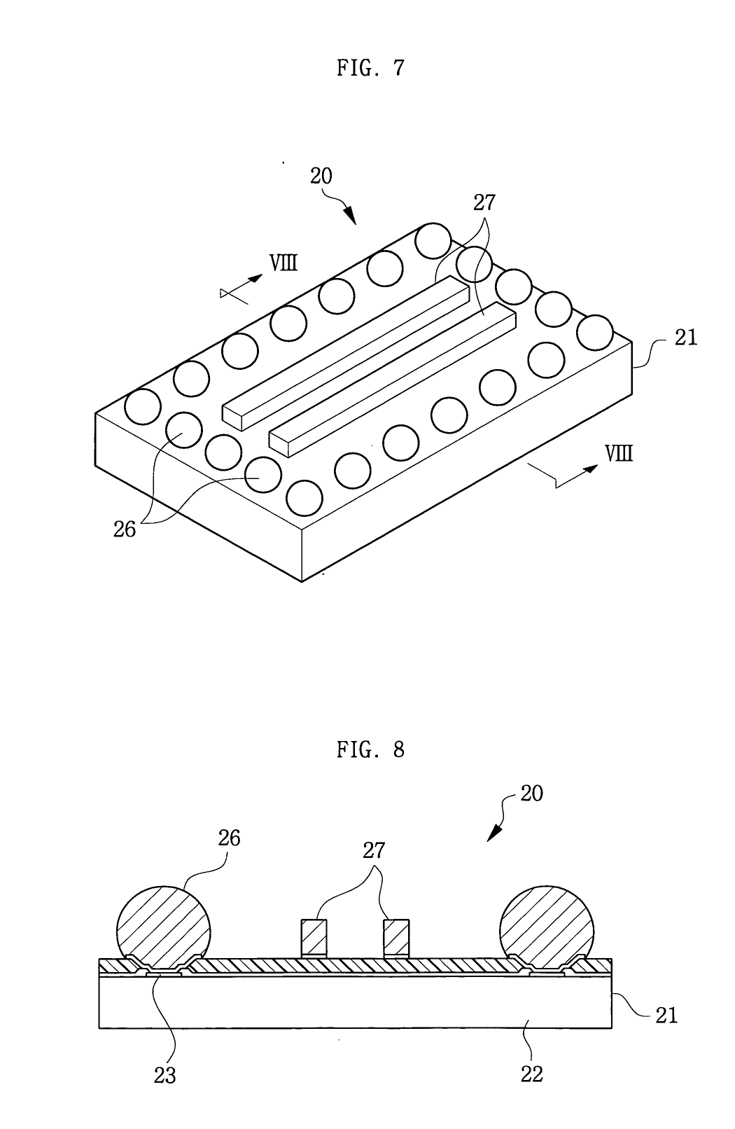

The aforementioned flip chip device 10 employs a center pad type chip 11. However, an edge pad type chip may be alternatively implemented in the flip chip device. For example, consider another exemplary, non-limiting embodiment of the flip chip device 20 shown in FIGS. 7 and 8. FIG. 7 is a perspective view of the flip chip device 20 having a solder bar 27 in accordance with an exemplary embodiment of the present invention, and FIG. 8 is a cross-sectional view taken along the line VIII-VIII of FIG. 7.

As shown in FIGS. 7 and 8, the flip chip device 20 according to another exemplary embodiment employs an edge pad type chip 21. Here, the solder bumps 26 may arranged in a peripheral region of the active surface of the chip 21, and the solder bar 27 may be arranged in a central region of the active surface. In other respects, the flip chip device 20 of this embodiment is similar to the flip chip device 10 of the previous embodiment.

It will be appreciated that the flip chip device 20 may be mounted on and flip chip bonded to a substrate having land pads (with or without associated metal cores). The land pads of the substrate will, however, be relocated (as compared to the location of land pads associated with the previous exemplary embodiments) to positions that appropriately correspond to the peripheral locations of the solder bumps 26 and the central location of the solder bar 27.

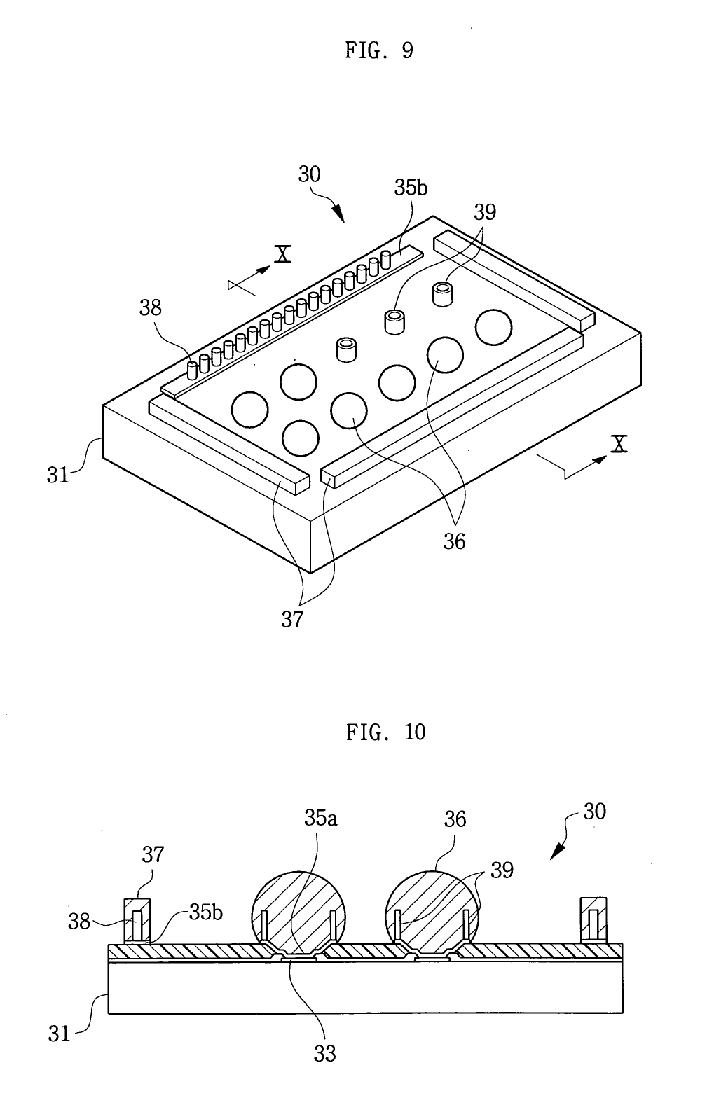

Another exemplary, non-limiting embodiment of the flip chip device 30 is illustrated in FIGS. 9-10. FIG. 9 is a partially cut away perspective view of a flip chip device 30 having a solder bar 37 in accordance with an exemplary embodiment of the present invention, and FIG. 10 is a cross-sectional view taken along the line X-X of FIG. 9. Referring to FIGS. 9 and 10, the flip chip device 30 may include a plurality of third metal cores 38 embedded within the solder bar 37. The third metal cores 38 may be arranged in a row along the solder bar 37 and extend from the part 35b of the UBM layer that is provided underneath the solder bar 37. Additionally, fourth metal cores 39 may be embedded in respective solder bumps 36. The fourth metal cores 39 may extend from the part 35a of the UBM layer that is provided underneath the solder bumps 36.

As in the previous exemplary embodiments, the solder bumps 36 and the solder bar 37 may be fabricated from, for example, mainly tin (Sn) and additionally include one or more of lead (Pb), nickel (Ni), silver (Ag), copper (Cu), bismuth (Bi) and their alloy. The third and the fourth metal cores 38 and 39 should maintain their shapes without melting during the reflow process of the solder bumps 36 and the solder bar 37. Therefore, the metal cores 38 and 39 should have a melting point greater than that of the solder bumps 36 and the solder bar 37. To this end, the metal cores 38 and 39 may be fabricated from one or more of nickel (Ni), copper (Cu), platinum (Pt), palladium (Pd), gold (Au) and their alloy. The metal cores 38 and 39 may be fabricated from other alternative materials that are well known in this art, and therefore a detailed description of the same is omitted.

The third metal cores 38 may promote the mechanical connection of the solder bar 37 to the UBM layer 35b. Generally, an adhesive strength between the metal cores 38 and the UBM layer 35b may be about three times greater than an adhesive strength between the solder bar 37 and the UBM layer 35b. Accordingly, even if thermal stress is produced in the solder bar 37 (e.g., due to a difference in the coefficient of thermal expansion (CTE) between the flip chip device 30 and the substrate), the metal cores 38 mechanically support the solder bar 37 so that the solder bar 37 does not become separated from the UBM layer 35b. In a similar fashion, the fourth metal cores 39 may mechanically support the solder bumps 36 so that the solder bumps 36 do not become separated fro the UBM layer 35a.

Furthermore, the third and the fourth metal cores 38 and 39 reinforce the solder bar 37 and the solder bumps 36, thereby preventing the solder bar 37 and the solder bumps 36 from collapsing during the solder reflow process. Also, the metal cores 38 and 39 act as obstacles to crack propagation when any crack occurs in the solder bar 37 and the solder bumps 36 due to thermal stress, for example.

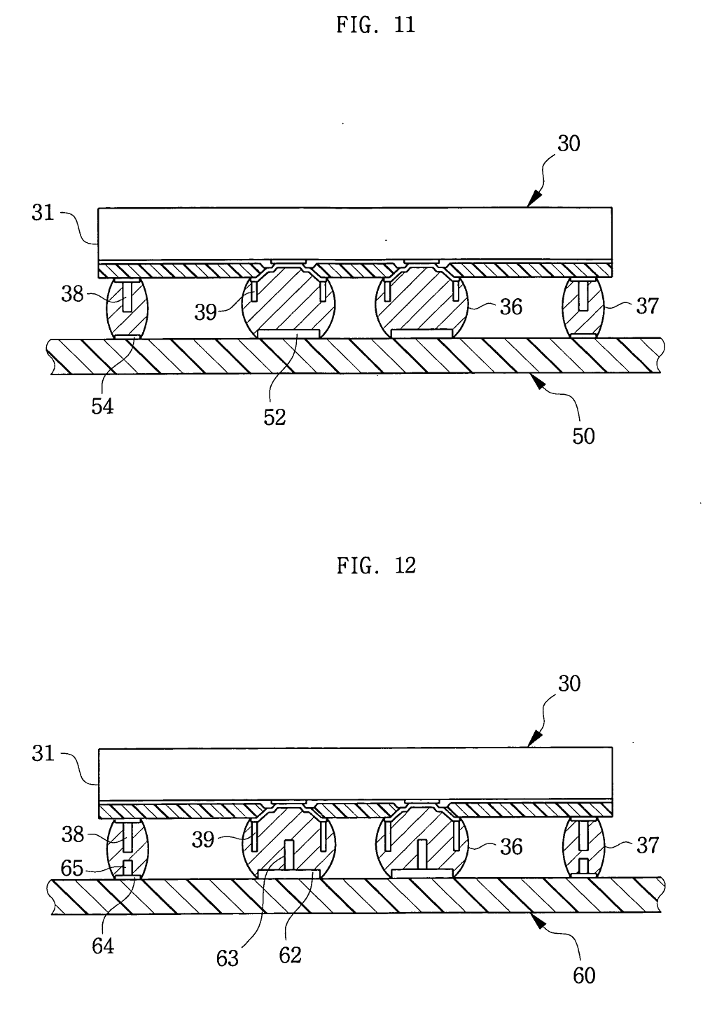

The flip chip device 30 according to another exemplary embodiment may be mounted on and flip-chip bonded to the substrate 50 (which may have land pads without associated metal cores), as shown in FIG. 11. Alternatively, the flip chip device 30 may be mounted on and flip-chip bonded to the substrate 60 (which may have land pads with associated metal cores 63, 65), as shown in FIG. 12. Exemplary embodiments of both types of substrates 50 and 60 have been described above with reference to FIGS. 3-6.

When the third metal cores 38 (of the flip chip device 30) and the second metal core 65 (of the substrate 60) are used together in the solder bar 37, as shown in FIG. 12, the metal cores 38 and 65 may be provided so that they do not interfere with (e.g., abut against) each other during the solder reflow process, in which the flip chip device 30 and the substrate 60 are moved toward each other. For example, as shown in FIG. 12, the metal cores 38 and 65 may be of such a height that they do not to meet together. The metal cores 38 and 65 may also be provided at offset locations and/or have cooperating shapes so that they do not meet together.

Similarly, the fourth metal cores 39 (of the flip chip device 30) and the first metal cores 63 (of the substrate 60), which are used together in the solder bumps 36, may be provided so that they do not interfere with each other during the solder reflow process. For example, as shown in FIG. 12, the metal cores 39 and 63 may have cooperating shapes: i.e., the fourth metal cores 39 are in the form of hollow cylinders (see also FIG. 9), while the first metal cores 63 are in the form of solid pins that may be partially inserted into the hollow interior of the fourth metal cores 39. Thus, the metal cores 39 and 63 do not meet together. Other cooperating shapes would be known to one of ordinary skill in this art. The metal cores 39 and 63 may also be provided at different locations or have short height so they do not meet together.

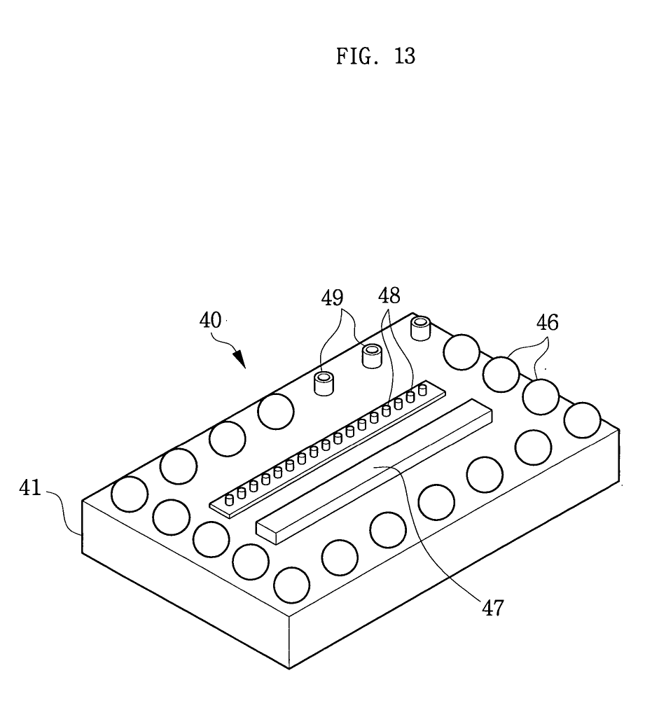

FIG. 13 is a partially cut away perspective view of a flip chip device 40 having a solder bar 47 in accordance with another exemplary, non-limiting embodiment of the present invention. The flip chip device 40 shown in FIG. 13 is similar to the flip chip device 30 shown in FIG. 9 since metal cores 48 are embedded within the solder bar 47 and since metal cores 49 are embedded within the solder bumps 46. However, similar to the second embodiment, the flip chip device 40 of the fourth exemplary embodiment employs an edge pad type chip 41. Accordingly, the solder bumps 46 are arranged in a peripheral region of the active surface of the chip 41, and the solder bar 47 is arranged in a central region of the active surface.

Many of the foregoing embodiments have involved positioning the solder bumps and solder bars on the flip chip device. However, the exemplary embodiment of the invention are not so limited, and those skilled in the art will appreciate that the solder bars and the solder bumps may be applied to the to the substrate instead of (or in addition to) the flip chip device. Further, those skilled in the art will appreciate that the solder bumps and the solder bars may have a variety of shapes. For example, the solder bar may have a cross sectional profile that forms a circle, a triangle, or other geometric shape (as opposed to the rectangular shaped profile shown in FIG. 1).

Further, the exemplary embodiments of the invention are not limited as to the specific shapes of the cores associated with the flip chip device and the cores associated with the substrate. It will be readily apparent to those skilled in the art that a variety of core shapes may be implemented. For example, the second core 65 depicted in FIG. 5 may be discontinuously provided, or it may have sides that are curved.

While exemplary embodiments of this invention have been particularly shown and described, it will be understood by those skilled in the art that various changes in form and details may be made therein without departing from the spirit and scope of the invention as defined by the appended claims.

1. A semiconductor device comprising:
a semiconductor chip having an active surface, a plurality of chip pads formed on the active surface, and a protective layer formed on the active surface, such that the chip pads are exposed through the protective layer;
a plurality of solder bumps provided on the active surface and electrically connected to the respective chip pads; and
a solder bar provided on a portion of the protective layer.

2. The device of claim 1, wherein the solder bumps are arranged in a central region of the active surface and the solder bar is arranged in a peripheral region of the active surface.

3. The device of claim 1, wherein the solder bumps are arranged in a peripheral region of the active surface and the solder bar is arranged in a central region of the active surface.

4. The device of claim 1, further comprising an under bump metal layer interposed between the solder bar and the protective layer.

5. The device of claim 4, further comprising at least one metal core formed on the under bump metal layer and embedded within the solder bar.

6. The device of claim 5, wherein the metal core is fabricated from at least one of nickel (Ni), copper (Cu), platinum (Pt), palladium (Pd), gold (Au) and alloys thereof.

7. The device of claim 1, wherein the solder bar is not higher than the solder bumps.

8. A structure comprising:
a semiconductor device including:
a semiconductor chip having an active surface, a plurality of chip pads formed on the active surface, and a protective layer formed on the active surface, such that the chip pads are exposed through the protective layer;
a plurality of solder bumps provided on the active surface and electrically connected to the respective chip pads; and
a solder bar provided on a portion of the protective layer; and
a substrate on which the semiconductor device is mounted, the substrate including first land pads to which the solder bumps are joined and a second land pad to which the solder bar is joined.

9. The structure of claim 8, wherein the solder bumps are arranged in a central region of the active surface and the solder bar is arranged in a peripheral region of the active surface.

10. The structure of claim 8, wherein the solder bumps are arranged in a peripheral region of the active surface and the solder bar is arranged in a central region of the active surface.

11. The structure of claim 8, wherein the semiconductor device further includes an under bump metal layer interposed between the solder bar and the protective layer.

12. The structure of claim 11, wherein the semiconductor device further includes at least one metal core formed on the under bump metal layer and embedded within the solder bar.

13. The structure of claim 12, wherein the metal core is fabricated from at least one of nickel (Ni), copper (Cu), platinum (Pt), palladium (Pd), gold (Au) alloys thereof.

14. The structure of claim 8, wherein the substrate further includes at least one metal core formed on the second land pad and embedded within the solder bar.

15. The structure of claim 14, wherein the metal core is fabricated from at least one of nickel (Ni), copper (Cu), platinum (Pt), palladium (Pd), gold (Au) alloys thereof.

16. The device of claim 1, wherein the solder bar is electrically insulated from the semiconductor chip.

17. The device of claim 1, wherein the solder bar is discontinuously provided on the protective layer.

18. The device of claim 1, wherein the solder bar is continuously provided on the protective layer.

19. The device of claim 1, wherein the solder bar has a longitudinal axis with a straight portion.

20. The device of claim 1, wherein the solder bar has a rectangular shaped profile in cross section.

21. The device of claim 1, further comprising at least one metal core embedded within the solder bar, wherein the metal core has a melting point that is greater than that of the solder bar.

22. The device of claim 21, wherein the at least one metal core is a solid body having a cylindrical shape.

23. The device of claim 1, further comprising a metal core embedded in at least one of the solder bumps, wherein the metal core has a melting point that is greater than that of the at least one solder bump.

24. The device of claim 23, wherein the metal core is a hollow body having a cylindrical shape.

25. The device of claim 2, wherein the solder bar completely surrounds a periphery of the solder bumps.

26. The device of claim 25, wherein the solder bar has a rectangular shape.

27. The device of claim 3, wherein the solder bar is discontinuously provided, and each section of the solder bar has a straight longitudinal axis.

28. The device of claim 1, further comprising an under bump metal layer interposed between each solder bumps and the respective chip pad.

29. The device of claim 28, further comprising a metal core formed on the under bump metal layer and embedded within at least on of the solder bumps.
